(19) United States
(12) Patent Application Publication
(10) Pub. No.: US 2024/0309540 A1
(43) Pub. Date: Sep. 19, 2024

(54) DEVICE AND METHOD FOR PRODUCING A MONOCRYSTALLINE SILICON ROD IN A ZONE-MELTING PULLING SYSTEM

(71) Applicant: SILTRONIC AG, Munich (DE)

(72) Inventor: Patrick Moos, Pleiskirchen (DE)

(21) Appl. No.: 18/550,134

(22) PCT Filed: Mar. 1, 2022
(86) PCT No.: PCT/EP2022/055084

§ 371 Date: Sep. 12, 2023

(30) Foreign Application Priority Data
Mar. 15, 2021 (EP) 21162639.5

(51) Int. Cl. C30B 13/28; C30B 29/06

(52) U.S. Cl. CPC C30B 13/285; C30B 29/06

(57) ABSTRACT

The invention relates to a method and a device for pulling a monocrystalline silicon rod in a pulling system for zone melting, the method comprising the following steps: (I) providing a stock rod made of silicon, which comprises an azimuthal groove at one end; (2) attaching a lower part, which comprises three gripping arms, each gripping arm being shaped such that one end fits into the azimuthal groove of the stock rod and another end is rotatably attached to the lower part; (3) suspending the lower part, together with the stock rod, on an upper part, which contains a connecting element connected to a pulling shaft of the zone-melting pulling system, such that the upper part and the lower part are radially interlockingly connected to each other, the upper part comprising an element for radial orientation, and three length-adjustable spacing elements being attached to the upper part such that the spacing elements can apply force to respective gripping arms; (4) moving the element for radial orientation such that the axis of rotation of the stock rod at the end at which the groove is located corresponds to the axis of rotation of the pulling shaft; (5) setting the length-adjustable spacing elements such that the axis of rotation of the stock rod at the end remote from the groove corresponds to the axis of rotation of the pulling shaft; (6) pulling a conical part of a monocrystalline rod; (7) pulling a cylindrical part of the monocrystalline rod.

The subject matter of the invention is a device and a method for producing a monocrystalline rod from silicon in a zone pulling installation using an azimuthally grooved feed rod.

On an industrial scale, zone pulling is used in particular for producing single crystals from silicon. This involves obtaining a single crystal from a polycrystalline feed rod, though optionally a feed rod of monocrystalline silicon can also be used.

For this purpose, the feed rod is incipiently melted at one end with the aid of a radio-frequency coil (inductor) and a monocrystalline seed crystal is attached to the resulting melt droplet. Material progressively melted from the feed rod serves as a supply for a single crystal subsequently growing on the seed crystal. A section of length referred to as a thin neck (neck) is firstly crystallized, in order to divert dislocations from the crystal lattice. Subsequently, the diameter of the growing single crystal is increased to a desired diameter in a section of length referred to as the initial cone (seed cone). After that, a section of length in which the single crystal has the desired diameter is produced. To complete the method, a section of length referred to as the end cone is produced. Optionally, the method may also be completed without an end cone, though then a part at the end of the section of length with the desired diameter is unusable for the intended further processing because it has dislocations.

The feed rod is in this case mounted with one end on a rotatable shaft (pulling shaft) in such a way that it does not slip-even if the direction of rotation changes abruptly. There is also the requirement that the middle of the other end of the feed rod is at all times on the axis of rotation of the pulling shaft during the crystal pulling. If the center of the other end were to move away from the axis of rotation of the pulling shaft, that would lead to considerable influencing of the melting by the pulling coil, which in turn may adversely influence the entire pulling process.

This effect can be very easily observed if the frequency of the radio-frequency coil (pulling coil) is measured as a function of time, since the frequency is load-dependent, and is consequently a function of the distance of the feed rod from the coil.

Currently available on the market are monocrystalline rods of silicon with a diameter of nominally up to 200 mm that have been produced by the zone pulling process. In addition to the length of the rod to be pulled, the target diameter of the monocrystalline rod in this case determines of course the weight of the feed rod necessary for this.

The development toward longer monocrystalline rods for increasing the yield and also the development toward greater diameters of the monocrystalline rod therefore necessarily require a greater weight of the respective feed rod that is fitted into the pulling installation and has to be both precisely and securely held there on the pulling shaft.

Patent application JP 2019 167 254 A2 describes for example a device for holding a feed rod in an installation for zone melting which includes a connecting element between the pulling shaft and the feed rod, a multiplicity of locking parts, a horizontal positioning part for setting the horizontal position of the feed rod and a shielding part for shielding from radiant heat.

The device described in the cited prior art is suitable in principle for positioning feed rods in an installation for zone pulling. However, in particular when using feed rods of a very high weight and great lengths, it has been found that the fitting proves to be too insecure, and consequently also too imprecise. Moreover, the device is not easy to attach, and so the heavy feed rod has to be introduced into the pulling installation and fixed there in a way that is complicated and usually entails risk. The second disadvantage is that there is no possibility of setting the angle of the feed rod with regard to its ideal line in the pulling installation, or this can only be optimized with great difficulty, which has the result that the yield of the pulled rods is reduced.

The object of the invention is therefore to provide an improved form of the device of the prior art that does not have the aforementioned disadvantages.

The object of the invention is also to provide a method for fitting a feed rod that is capable of also fitting very heavy feed rods securely and precisely into the zone pulling installation.

The object is achieved by the methods and devices described in the claims.

The features specified with regard to the embodiments set out above of the method according to the invention can be correspondingly applied to the products according to the invention. Conversely, the features specified with regard to the embodiments set out above of the products according to the invention can be correspondingly applied to the method according to the invention. These and other features of the embodiments according to the invention are explained in the description of the figures and in the claims. The individual features can be realized either separately or in combination as embodiments of the invention. Furthermore, they can describe advantageous embodiments which are independently protectable.

### BRIEF DESCRIPTION OF THE FIGURES

FIG. 1 shows a specific embodiment according to the invention of an arrangement for holding a feed rod (101) in a crystal pulling installation for zone pulling.

A connecting element (108) lying on top in the form of an adapter, which is attached to the pulling shaft, holds an element for radial alignment of the device (107). The connecting element (108) is preferably designed in such a way that it can be screwed onto the pulling shaft by means of a thread, while at the same time it is secured by bolts, so that the thread cannot be undone of its own accord due to a sudden change in the direction of rotation of the arrangement as a whole.

Subsequently, an element for radial alignment (107) of the arrangement is attached. It comprises for example linear guides which ensure that a radial alignment of the arrangement can be carried out.

Three grippers (103) hold by one end an azimuthal groove (102) of the feed rod (101), the groove being provided in the vicinity of the end of the feed rod.

The gripping arms or grippers (103) are in this case attached to a lower part of the device by means of bolts or splints (104) in such a way that they can rotate and thus can grip the feed rod. With the aid of screws (105), which are attached to the upper part in such a way that they can exert force on the grippers, the feed rod (101) can on the one hand be fixed and on the other hand be aligned in such a way that the remote end of the feed rod (101) is aligned exactly centrally.

FIG. 2 shows the upper part of a configuration according to the invention of the device. The upper part may be screwed onto the pulling shaft by way of an adapter (206) and secured by way of bolts. Securing by means of bolts is appropriate because the overall arrangement is subjected to rapid changes of rotation, and so it is prevented from coming loose of its own accord.

Subsequently, an element for radial alignment (205) of the arrangement is attached. It comprises for example linear guides which ensure that a radial alignment of the arrangement can be carried out. The linear guides can be operated by screws (204).

The upper part also comprises a bearing (203), which serves for easily suspending a lower part. To be able to suspend the lower part, a corresponding opening in the upper part (202) is necessary. The upper part also comprises length-adjustable spacer elements (201), which are attached in such a way that they can exert force on gripping arms that are fastened to the lower part. A simple specific embodiment of a spacer element is a screw that is provided with counter nuts.

FIG. 3 shows the lower part of a configuration according to the invention of the device. Three gripping arms or grippers (301) are attached by means of bolts or rivets (302) in such a way that they can rotate and thus engage in the groove of the feed rod. The rotation of the gripping arms can in this case be set and fixed by a screw mechanism.

The lower part comprises a counter bearing (303), so that it can be easily suspended on the upper part. Preferably, the grippers or gripping arms (301) are produced monolithically from one piece.

FIG. 4 shows by way of example how the lower part (401) can be suspended in the upper part (402). The upper part in this case comprises a connecting element (403), which can be connected to the pulling shaft, and an element for radial alignment by means of a linear guide (404), with the aid of which the device can be radially aligned. The lower part, which is suspended in the upper part, comprises movable gripping arms (405), which are attached by means of rivets or splints secured by snap rings.

FIG. 5 shows in the detail a specific embodiment according to the invention of the element for radial alignment of the device in the pulling installation (linear guide). One or more leaf springs (503), which bear the connecting element (502), rest on a base plate (501). By way of a screw (504), the connecting element (502) can be precisely adjusted horizontally in such a way that the position of the rod suspended in the device meets the specifications. A screw (505) is in this case used for countering the linear guide, in order to secure the position that has been set.

### DESIGNATIONS

101 Feed rod. The feed rod may consist of polycrystalline or monocrystalline semiconductor material.
102 Azimuthal groove on one side of a feed rod (101). In the example shown, the groove is asymmetrically formed, that is to say the diameter of the feed rod differs on the left and right of the groove.
103 Gripping arm, which is formed in such a way that one end fits into the azimuthal groove of the feed rod (102), and another end is fastened rotatably to the lower part.
104 Rivets, on which one end of the gripping arm is attached in such a way that the gripping arm can turn.
105 Screw (a length-adjustable spacer element is attached to the upper part in such a way that it can exert force on a gripping arm)
106 Connected to one another in a self-centering and detachable manner
107 Element for radial alignment
108 Connecting element lying on top
201 Screw (a length-adjustable spacer element is attached to the upper part in such a way that it can exert force on a gripping arm)
202 Opening, to allow the lower part to be suspended
203 Bearing for the lower part
204 Screws for horizontal adjustment in the linear guide
205 Element for radial alignment by means of a linear guide
206 Connecting element lying on top
301 Gripping arm
302 Rivet or splint secured by snap ring
303 Counter bearing to suspend the lower part in the upper part
401 Lower part
402 Upper part
403 Connecting element lying on top
404 Element for radial alignment by means of a linear guide
405 Movable gripping arms
406 Rivet or splint secured by snap ring
501 Base plate
502 Connecting element
503 Leaf spring
504 Screw for horizontal adjustment in the linear guide
505 Screw for countering the linear guide
506 Covering

### DETAILED DESCRIPTION OF EXEMPLARY EMBODIMENTS ACCORDING TO THE INVENTION

After analyzing the problems mentioned, the inventor realized that a preferred solution to the problems mentioned is to design a device for holding the feed rod in such a way that it is made up of at least two parts, with one part (referred to hereinafter as the lower part) being able to be mounted on the rod while it is still outside the crystal pulling installation. The second part of the device (referred to hereinafter as the upper part) is securely mounted on the pulling shaft in the crystal pulling installation.

The pulling shaft is the term used for the device that essentially performs two tasks in the pulling installation: (1) it ensures that the feed rod fastened to it is held while it possibly undergoes changing rotational speeds and/or directions of rotation and (2) the feed rod can be moved axially at a previously fixed (or possibly changing) speed.

The feed rod in this case supplies the material from which the later single crystal is to be produced. For pulling a single crystal from silicon, for example a polycrystalline feed rod of silicon is used. It goes without saying that a monocrystalline crystal, which for example is pulled by means of a Czochralski pulling process, can also be used as the feed rod. It is also possible to use other semiconductor materials for the feed rod.

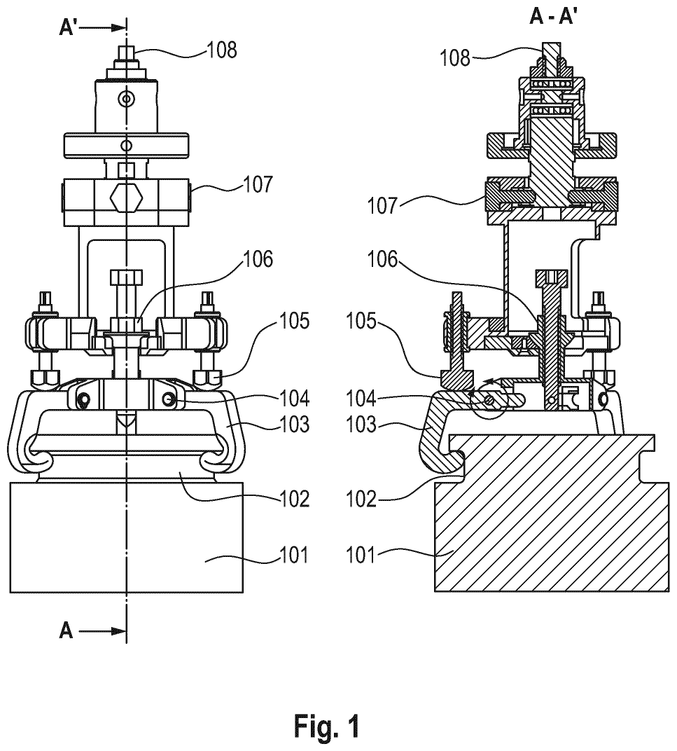

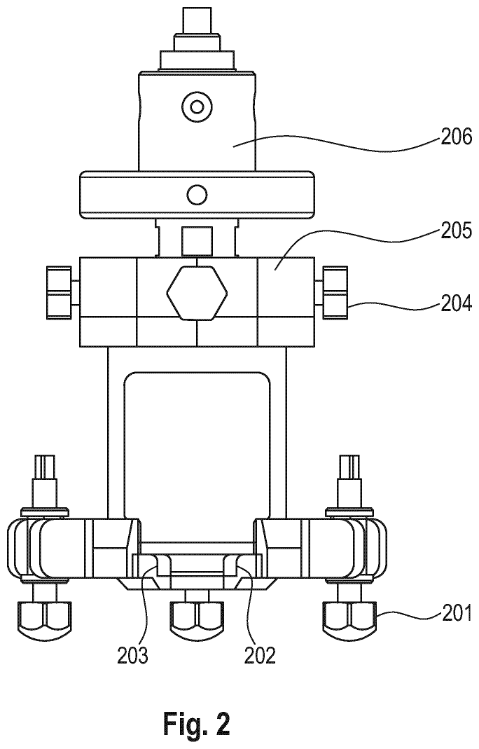

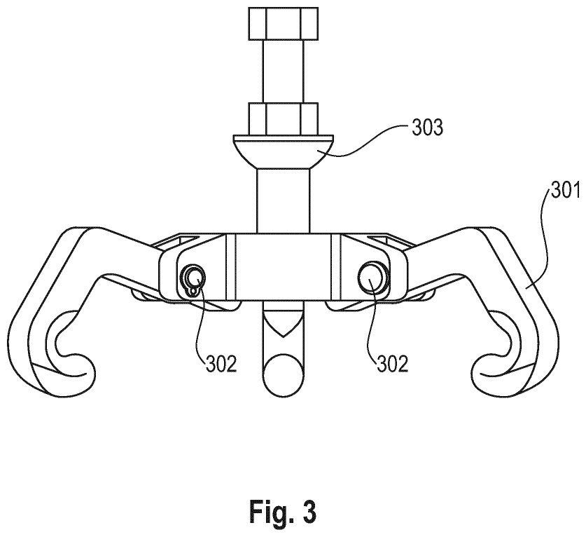

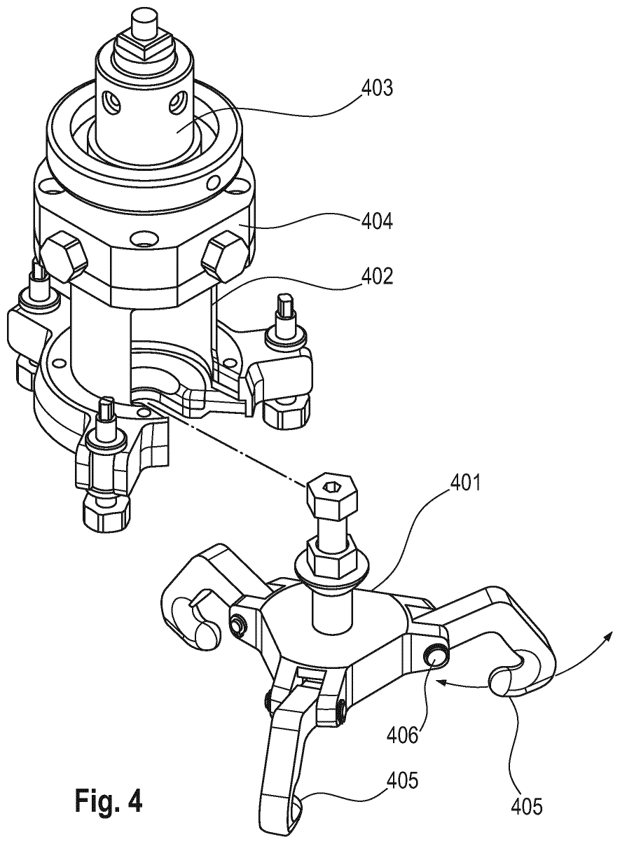

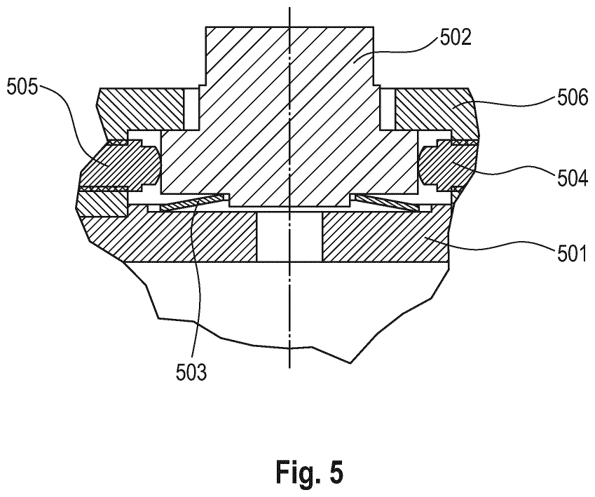

It is essential for the feed rod that it has the form of a cylinder, its lateral surface having in the vicinity of one side (upper side) a groove which is dimensioned in such a way that the feed rod can be held without breaking out. FIG. 1 shows in this respect by way of example a feed rod (101) with a correspondingly formed groove (102).

The weight of a feed rod may vary depending on the desired diameter and the length of the monocrystalline rod. A typical weight for monocrystalline rods of silicon may in this case be much more than 100 kg and in some cases even more than 200 kg.

The fixing of such a heavy feed rod in a pulling installation by the means available in the prior art is difficult and time-insensitive and entails risks. The weight of the feed rod must in this case be kept precisely upright in the pulling installation as long as it takes until it is mounted and aligned on the pulling shaft.

If the alignment takes place inadequately, this can lead to oscillation of the emitter frequency during the crystal pulling, which often leads to rod failure (breakage, or dislocation).

The inventor has realized that preferably a lower part of a device according to the invention is first attached to the feed rod while the feed rod is still outside the pulling installation. Particularly preferably, the feed rod is in this case horizontal.

The lower part of the device according to the invention (as shown for example in FIG. 3) preferably includes in this case three gripping arms or grippers (301), which are attached to the device by means of bolts or rivets (302) in such a way that they can rotate.

When the lower part is attached to the feed rod, the grippers (301, 103) engage in the groove (102) of the feed rod (101) and fix it there.

In the center of the lower part there is an adjusting screw, which can be used for opening or closing all of the gripping arms simultaneously. With the aid of this adjusting screw, the lower part is fastened to the feed rod by way of the gripping arms.

The feed rod is preferably fitted into the pulling installation together with the lower part of the device mounted on it.

In this case, the counter bearing (303) of the lower part is first suspended in a bearing of the upper part (203). This bearing is preferably configured in such a way that the lower part can be easily suspended, in particular a corresponding opening in the upper part (202) is necessary for this, which allows lateral access for this.

The lower part is consequently connected to the upper part radially with a form fit, the bearing used having the effect that the parts are additionally connected to one another in a self-centering and also detachable manner.

The upper part preferably comprises an element which serves for the radial alignment of the feed rod. The upper part preferably includes a linear guide with the aid of which the feed rod can be set in such a way that the axis of rotation of the pulling shaft coincides with the axis of rotation of the feed rod. The linear guide is in this case preferably arranged in such a way that the path of movement is perpendicular to the axis of rotation of the pulling shaft.

When setting up, preferably the linear guide is first used to set up the feed rod in such a way that the axis of rotation of the groove located in the feed rod coincides with the axis of rotation of the pulling shaft. The desired position of the linear guide is subsequently preferably secured by the countering screws (505) located in the device. The success of the measure can be checked for example by rotating the pulling shaft with the feed rod fastened to it and at the same time checking the concentricity.

The upper part likewise preferably comprises length-adjustable spacer elements (105), such as for example screws, which are attached in such a way that they can exert force on the gripping arms (103), which are fastened to the lower part.

The setting of these length-adjustable spacer elements (201) has the effect that the feed rod can be aligned along its axis. The feed rod is in this case preferably set up in such a way that the axis of rotation of the pulling shaft coincides with the axis of rotation of the feed rod. In particular, it is ensured that the axis of rotation at the end of the feed rod opposite from the groove coincides with the axis of rotation of the pulling shaft. This can be checked by checking the concentricity.

FIG. 1 shows two views of a feed rod (101), which is clamped in the device according to the invention.

Once the feed rod has been inserted, the installation can be closed and the crystal pulling commenced, by first pulling an initial cone which, after reaching a target diameter, goes over into a cylindrical part. After reaching a desired length of the monocrystalline rod, an end cone is pulled. After completing the crystal pulling, the monocrystalline rod can be removed from the installation and a new feed rod prepared.

Ideally, during the crystal pulling of a first crystal, a feed rod is already attached to a lower part as provided by the invention, which further reduces the setting-up times of the installation considerably.

1.-4. (canceled)

5. A device for holding a feed rod in a pulling installation for zone melting, the device comprising:
an upper part, the upper part comprising:
a connecting element, which serves for the fitting into the pulling installation; and
a radial alignment element configured to radial align the upper part in the pulling installation:
a lower part, the lower part comprising three gripping arms, the three gripping arms being formed in such a way that one end fits into a groove in the lateral surface of the feed rod, and another end is attached rotatably; and
three length-adjustable spacer elements attached to the upper part in such a way that the length-adjustable spacer elements are configured to exert force respectively onto a gripping arm, of the gripping arms,
wherein the upper part and the lower part are connected by a bearing, the bearing having the effect that a connection is radially with a form fit in a self-centering and detachable manner with respect to one another.

6. The device as claimed in claim 5, wherein:
the radial alignment element comprises linear guides, which are arranged in such a way that the respective linear guidance is configured take place perpendicularly to the pulling shaft.

7. The device as claimed in claim 5, wherein the three gripping arms have been produced monolithically from one piece.

8. A method for pulling a monocrystalline rod from silicon in a pulling installation for zone melting, including the following steps
providing a feed rod of silicon, which at one end comprises a groove in the lateral surface;
attaching a lower part of a device for holding the feed rode, the lower part comprising three gripping arms, formed in such a way that one end fits into the groove of the feed rod and another end is attached rotatably to the lower part,
suspending the lower part together with the feed rod on an upper part of the device, the upper part comprising:
a connecting element, which is connected to a pulling shaft of the pulling installation, so that the upper part and the lower part are connected to one another by a bearing which has the effect that the connection is radially with a form fit and in a self-centering manner;
a radial alignment element; and
three length-adjustable spacer elements attached to the upper part in such a way that they are configured to exert force respectively onto a gripping arm:
moving the radial alignment element so that an axis of rotation of the feed rod at the one end at which the groove is located coincides with an axis of rotation of the pulling shaft;
setting the length-adjustable spacer elements so that the axis of rotation of the feed rod at an end opposite from the groove coincides with the axis of rotation of the pulling shaft;
pulling a conical part of the monocrystalline rod; and
pulling a cylindrical part of the monocrystalline rod.
